(19) United States
(12) Patent Application Publication
(10) Pub. No.: US 2008/0153008 A1
(43) Pub. Date: Jun. 26, 2008

(54) Optical Element, Method for Production Thereof and Display Device

(76) Inventors: Masahiko Hayashi, Tokyo (JP); Toshiaki Suzuki, Tokyo (JP); Keisuke Tsukada, Tokyo (JP); Akiyoshi Shibuya, Tokyo (JP); Satoshi Tazaki, Tokyo (JP); Kazuyuki Obuchi, Tokyo (JP)

Correspondence Address: BIRCH STEWART KOLASCH & BIRCH, PO BOX 747, FALLS CHURCH, VA, 22040-0747, US

(21) Appl. No.: 10/589,784

(22) PCT Filed: Feb. 17, 2005
(86) PCT No.: PCT/JP2005/002487

§ 371 Date: Aug. 17, 2006

(30) Foreign Application Priority Data
Feb. 18, 2004 (JP) 2004-041050
Aug. 31, 2004 (JP) 2004-251509

(51) Int. Cl. G03F 1/06

(52) U.S. Cl. 430/2

(57) ABSTRACT

The present invention is to provide an optical element in which both a good light diffusion performance and a good light transmittance are achieved and which is less subject to environmental influence, a method for production thereof and a display device using the optical element. An optical element including a molded body containing a resin having an alicyclic structure, wherein a fine hologram surface diffusion pattern has been precisely formed is provided. It is preferable that the optical element is a light diffusion plate or a light diffusion sheet. Further, it is preferable that the optical element is a molded body made by injection-molding.

### TECHNICAL FIELD

The present invention relates to an optical element, a method for production thereof and a display device such as a flat-panel display device using the same. More particularly, the present invention relates to an optical element in which a fine hologram surface diffusion pattern has been precisely formed and which is less subject to environmental influence, a method for production thereof and a display device using the same.

### BACKGROUND ART

Conventionally, as a means to control an output angle of light, optical elements to which various shapes are given on a surface of a transparent member are used in a display device using liquid crystal, EL and the like. It has been started to equip instruments such as mobile phones with an EL display device, and it is anticipated that the range of application of the EL display device will be expanded in the future. A liquid crystal display device has been widely used for many instruments such as mobile terminals, in-vehicle panels, personal computer and TV, and it is anticipated that the liquid crystal display devices will grow in size and offer advantages in their properties, and will be used as a substitute for CRT display devices.

In the liquid crystal display device, the liquid crystal itself does not emit the light, and thus requires a light source from an outside. Systems to provide the light source that have been brought into practice include a side light system in which the light source is disposed at a side edge of the liquid crystal display device, and a direct system in which the light source is disposed at a back of the liquid crystal display device. In the side light system, a device unit can be thinned, but a luminance is low. Thus, the direct system is suitable for the large-screen liquid crystal display device which requires the high luminance.

In the liquid crystal display device with the direct system, light sources such as multiple fluorescent tubes are disposed at the back of a device enclosure and the light incident on a light diffusion plate is diffused and converted into planar light having a uniform luminance. If necessary, the device is provided with a reflection plate behind the fluorescent tubes, gradation printing onto a light emitting surface of the light diffusion plate, a fine shape on the surface of the plate to enhance a diffusion function, and a light condensing sheet and a light diffusion sheet on the light emitting surface of the light diffusion plate. The light diffusion plate is required to have a good balance between a light transmittance and a light diffusiveness, have no warping and have sufficient strength. When the fine shape is imparted onto the surface, it is required that the shape is excellent in precision and the shape is not changed by influence of the environment.

Usually, when the light diffusiveness is enhanced, the light transmittance is reduced. Thus the diffusive performance and the transmittance are in trade-off relationship, that is, the both are not well-achieved. However, if the light diffusiveness can be enhanced whereas the light transmittance is kept high, the costly light condensing sheet such as prism sheet and the light diffusion sheet can be omitted. It is thereby possible to obtain the liquid crystal display device economically.

As one of techniques therefor, a technology in which the functions of the light condensing sheet and the light diffusion sheet are incorporated by imparting special shapes onto the surface of a light guide plate or the light diffusion plate has been known. In Patent Document 1 (JP 2004-4417-A), the light diffusion sheet obtained by applying a polystyrene bead-containing ultraviolet ray-cured resin onto triacetylcellulose, in which an average roughness at a center line (Ra, μm) is 0.1≦Ra≦0.4 and a ratio of Ra to an average mountain and valley spacing (Sm, μm), i.e., Ra/μm is 0.005 or less has been exemplified. However, the light diffusiveness is insufficient in this light diffusion sheet. As a particular example of the technology for enhancing the light diffusiveness while keeping high light transmittance, it has been known to use the shape referred to as a hologram surface diffusion pattern. The shape referred to as the hologram surface diffusion pattern is a shape having a fine asperity, and is formed on a photosensitive material by fixing a speckle pattern which is fluctuation of small spotted random light intensity produced at the side opposed to the light source when the light such as laser whose phases are uniform enters into a light diffusion element as described in Patent Document 2 (JP Sho-59-131902-A). Such a hologram surface diffusion pattern is a surface scattering pattern whereby a direction of the light is controlled and the light is made into a uniform state.

As described in Patent Document 3 (JP 2000-100621-A), there is known a method in which the shape made of the photosensitive material is molded with a resin such as epoxy resin or a metal by electrotyping and then transcribed onto another transparent material. Bichromic acid gelatin, acrylic monomer-containing compounds and photoresists are used as the photosensitive material. The transparent materials are, for example, thermoplastic resins such as acrylic resins.

In these examples, most of the photosensitive materials are highly water-absorbable resins. Thus, when the photosensitive material itself is used as the hologram surface diffusion pattern for the optical element, there has been a problem that the fine shape is not kept because the pattern is affected by the environment. When transcribed onto another transparent material, there have been problems that the fine shape is not transcribed well because the resin of the transparent material is highly viscous and that the fine shape is not kept by being affected by the environment because the acrylic resin is also highly water-absorbable.

| | |
|---|---|
| Patent Document 1: | JP 2004-4417-A |
| Patent Document 2: | JP Sho-59-131902-A |
| patent Document 3: | JP 3413519 B |

### DISCLOSURE OF INVENTION

### Problem to be Solved by the Invention

The object of the present invention is to provide an optical element which has both a good light diffusion performance and a good light transmittance and is less subject to environmental influence, a method for production thereof, and a display device using the optical element.

### Means for Solving Problem

As a result of an extensive study to solve the above problems, the present inventors have found out that, by constituting an optical element having a fine hologram surface diffusion pattern using a resin having an alicyclic structure, the pattern is precisely formed. It is further found out that an optical element which is less subject to environmental influence can be obtained thereby and the optical element can be utilized suitably for a display device. The present inventors have thus completed the present invention based on these findings.

That is, the present invention provides:

(1) an optical element comprising a molded body containing a resin having an alicyclic structure, the molded body having a hologram surface diffusion pattern formed on at least one surface thereof;
(2) the optical element according to (1) wherein the hologram surface diffusion pattern is composed of a fine asperity, an arithmetic average roughness Ra of the asperity is 0.5 to 10 μm, and a ratio of the arithmetic average roughness Ra to a mean spacing Sm (Ra/Sm) of the asperity is 0.01 to 0.9;
(3) the optical element according to (1) or (2) wherein the optical element has a single layer structure;
(4) the optical element according to any one of (1) to (3) wherein the optical element is a light diffusion plate or a light diffusion sheet;
(5) the optical element according to any one of (1) to (4) wherein the surface has a rectangular planar shape and a length of its diagonal is 200 mm or more;
(6) the optical element according to any one of (1) to (5) wherein said element is obtained by injection molding;
(7) a display device comprising the optical element according to any one of (1) to (6); and
(8) a method for producing the optical element according to any one of (1) to (6) comprising: a step of preparing a stamper having a fine asperity formed on its surface, wherein an arithmetic average roughness Ra of the asperity is 0.5 to 10 μm, and a ratio of the arithmetic average roughness Ra to a mean spacing Sm (Ra/Sm) of the asperity is 0.01 to 0.9; a step of providing a mould wherein the stamper has been incorporated, and a step of injection-molding a resin having an alicyclic structure using the mould, to obtain a molded body wherein the fine asperity on the surface of the stamper is transcribed on a surface of the molded body.

### EFFECT OF THE INVENTION

The optical element of the present invention has the precisely formed fine hologram surface diffusion pattern, has both the good light diffusion performance and the good light transmittance, is less subject to the environmental influence, and can be simply formed and in a large size. Since the display device of the present invention has the aforementioned optical element of the present invention, the display device has high luminance, can be easily produced with low cost, has high durability and can be produced in large size. In the method for producing the optical element of the present invention, the optical element of the present invention can be easily produced.

### BRIEF DESCRIPTION OF DRAWINGS

FIG. 1 is a perspective view schematically showing a combination of the optical element of the present invention and a prism sheet.

FIG. 2 is a sectional view showing an example of an output angle of optimal diffusion light from the optical element in the combination of the optical element and the prism sheet shown in FIG. 1.

FIG. 3 is a sectional view showing one example of a shape of a reflection plate when the optical element is combined with the reflection plate.

FIG. 4 is a sectional view showing one embodiment of the display device of the present invention.

FIG. 5 is a perspective view showing one example of methods for making a hologram surface diffusion pattern.

### EXPLANATIONS OF LETTERS OR NUMERALS

1 Optical element
2 Prism sheet
3 Cold cathode tube
4 Reflection plate
5 Hologram surface diffusion pattern
6 Optical sheet
7 Liquid crystal panel
8 Light diffusion plate for pattern making
9 Photosensitive material
10 Shielding face
11 Coherent light

### BEST MODES FOR CARRYING OUT THE INVENTION

The optical element of the present invention comprises a molded body containing a resin having an alicyclic structure. The optical element of the present invention is characterized by having a precisely formed fine hologram surface diffusion pattern and being less subject to the environmental influence. In the optical element produced by injection molding using a resin other than the alicyclic structure-containing resin such as acrylic resin, the hologram surface diffusion pattern is not sufficiently transcribed, and thus, even though the light transmittance is excellent, the light diffusiveness becomes insufficient.

The optical element of the present invention is less subject to the environmental influence, particularly the influence of humidity, and the size and the surface shape thereof are not changed. The larger the size of the optical element is, the more this feature is advantageous because of its good transcriptional property upon molding. In the size of the optical element of the present invention, when having a rectangular planar shape, the length of its diagonal is preferably 200 mm or more, more preferably 300 mm or more and particularly preferably 400 mm or more. The upper limit of the diagonal length is not limited, and may be typically 5 m or less and preferably 4 m or less.

As to the optical element of the present invention, the rectangular planar shape includes incompletely rectangular which have a cut-off shape on each side.

The optical element of the present invention may be used for the display device, and particularly may be used suitably for a liquid crystal display device. For example, the optical element may be made as a light guide plate, a light diffusion plate and a light diffusion sheet for the liquid crystal display device. As preferable embodiments when the optical element of the present invention is the light diffusion plate or the light diffusion sheet, various types described later may be enumerated. Particularly, these may be used suitably as the light diffusion plate or the light diffusion sheet used for a direct type backlight.

The resin having the alicyclic structure used for the present invention has the alicyclic structure in a main chain and/or a side chain, and it is preferable to contain the alicyclic structure in the main chain in terms of mechanical strength and heat resistance.

Examples of the alicyclic structure may include saturated cyclic hydrocarbon (cycloalkane) structures and unsaturated cyclic hydrocarbon (cycloalkene, cycloalkine) structures. The cycloalkane structure and the cycloalkene structure are preferable in terms of mechanical strength and heat resistance. Among them, the cycloalkane structure is preferable. The number of carbon atoms which constitute the alicyclic structure is not particularly limited, and is typically 4 to 30 and preferably 5 to 20. More preferably, when the number is in the range of 5 to 15, the mechanical strength, the heat resistance and a molding property of the light diffusion plate are highly balanced, which is suitable.

The percentage of a repeating units having the alicyclic structure in the resin having the alicyclic structure may be selected optionally depending on a purpose of use, and is typically 50% by weight or more, preferably 70% by weight or more and more preferably 90% by weight or more. When the percentage of the repeating unit having the alicyclic structure is excessively low, the heat resistance is reduced, which is not preferable. A repeating unit other than the repeating unit having the alicyclic structure in the resin having the alicyclic structure is optionally selected depending on the purpose of use.

Specific examples of the resin having the alicyclic structure may include (1) norbornene polymers such as a ring-opening polymerization product of norbornene monomers, a ring-opening copolymerization product of norbornene monomers with other monomers capable of being ring-opening copolymerized therewith, a hydrogenated compound thereof, an addition polymer of norbornene monomers, and an addition copolymer of norbornene monomers with other monomers copolymerizable therewith, (2) polymers of single-ring cyclic olefins and hydrogenated compounds thereof, (3) polymers of cyclic conjugate dienes and hydrogenated compounds thereof, and (4) vinyl alicyclic hydrocarbons polymers such as a polymer of vinyl alicyclic hydrocarbon monomers, a hydrogenated compound thereof, a polymer obtained by hydrogenating aromatic ring moieties of a polymer of vinyl aromatic monomers. Among them, in terms of heat resistance and mechanical strength, the norbornene polymers and the vinyl alicyclic hydrocarbon polymers are preferable, and the hydrogenated ring-opening (co)polymers of the norbornene monomers and the polymer obtained by hydrogenating aromatic ring moieties of the polymers of the vinyl aromatic monomers are more preferable.

In addition to the aforementioned resin having the alicyclic structure, the molded body which constitutes the optical element of the present invention may optionally contain other polymers, various additives, fillers or mixtures thereof. Examples of such other polymers may include rubbers or resins such as polybutadiene and polyacrylate.

Examples of the additives may include anti-oxidants, ultraviolet ray absorbers, photostabilizers, near-infrared ray absorbers, coloring agents such as dyes and pigments, lubricants, plasticizing agents, antistatic agents and fluorescent brightening agents.

The molded body which constitutes the optical element of the present invention may further contain a light diffusing agent in order to enhance the light diffusion effect. Examples of the light diffusing agent may include organic fine particles of, e.g., crosslinked methyl polymethacrylate, crosslinked polystyrene, crosslinked methyl methacrylate-styrene copolymer, crosslinked silicone and fluorine resins; and inorganic fine particles of, e.g., silica, silica-alumina, alumina, aluminium hydroxide, magnesium hydroxide, talc, glass flakes, glass beads, sodium silicate, calcium carbonate, barium carbonate and titanium oxide.

It is preferable that the optical element of the present invention is formed by injection molding because the complicated shape, e.g., a rectangle (such as an oblong) with cut-off that is widely used for the light diffusion plates may be easily made, and because the fine shape may be easily transcribed on the surface thereof by disposing the stamper in the mould as described later.

The optical element of the present invention has a hologram surface diffusion pattern formed on at least one surface thereof. Methods for forming the hologram surface diffusion pattern are not particularly limited, and examples thereof may include (1-1) a method for forming fine asperity by sandblasting with a polishing agent the flat and smooth surface of a substrate containing the resin having the alicyclic structure; (1-2) a method for forming the fine asperity by painting a paint containing fine particles on the flat and smooth surface of the substrate containing the resin having the alicyclic structure; (1-3) a method for forming the fine asperity by applying a curable resin containing the fine particles on the flat and smooth surface of the substrate containing the resin having the alicyclic structure and curing the resin by irradiating ultraviolet ray or electron beam; and (1-4) a method wherein for obtaining the molded body by preparing a stamper having fine asperity on its surface, preparing a mould in which the stamper is incorporated, and injection-moulding the resin having the alicyclic structure using the mould, to obtain the molded body in which the fine asperity on the surface of the stamper is transcribed on the surface of the molded body.

Among the above methods (1-1) to (1-4), the method (1-4) is particularly preferable. More preferable is a method comprising a step of preparing the stamper having the fine asperity formed on its surface, wherein an arithmetic average roughness Ra of the asperity is 0.5 to 10 μm, and a ratio of the arithmetic average roughness Ra to a mean spacing Sm, i.e., Ra/Sm of the asperity is 0.01 to 0.9; a step of providing the mould in which the stamper has been incorporated; and a step of injection-molding the resin having the alicyclic structure using the mould, to obtain the molded body having the fine asperity of the above stamper transcribed on the surface of the molded body.

In the above method (1-4), a time period required for producing one optical element is one molding cycle in the injection molding, and this method may be used suitably because of its high productivity. In the methods (1-2) and (1-3), the resulting optical element may become a dual layer or a triple layer consisting of the substrate and a coating layer(s), whereas the injection-molded article may be in a uniform single layer structure. When the present optical element has the structure of two or more layers, it is likely to cause the warping owing to the change of temperature or humidity. However, when the optical element is in the single layer structure, it is unlikely to cause the warping due to the multiple layer structure, and thus being preferable.

A material of the above stamper is typically a metal. Methods for forming the fine asperity shape on the surface of a plate such as a metal plate for obtaining a stamper may include (2-1) a method for making the stamper by sandblasting the surface of the plate using the polishing agent; (2-2) a method for making the stamper by forming the fine asperity shape by processing with a diamond processing tool, and (2-3) a method for making the stamper having the fine asperity surface by applying the curable resin on a flat and smooth substrate; onto the curable resin, fixing a speckle pattern obtained by passing the light such as laser whose phases are uniform through a light diffusion element such as ground-glass; and electrotyping the metal on the pattern surface fixed on the cured resin. Among them, the method (2-3) is preferable.

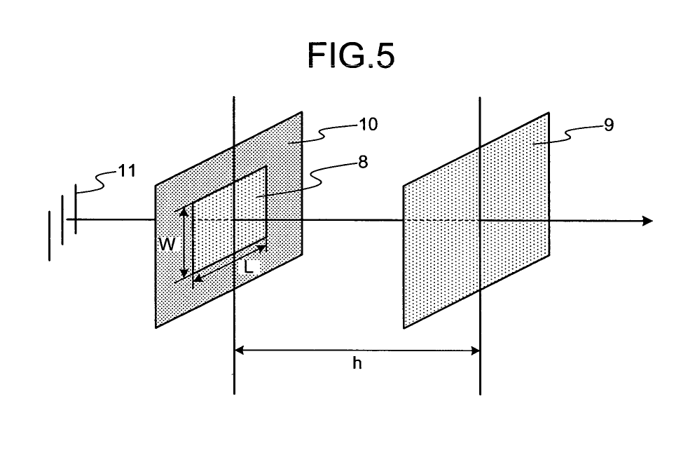

The above method (2-3) may be performed using a system, for example shown in FIG. 5, and in accordance with the following procedure.

The coherent light such as laser is entered into a light diffusion plate 8 for pattern making (light diffusion plate) through a shielding face 10 having an opening, and the speckle occurred thereby is recorded on a photosensitive material 9. As the light diffusion plate 8 for pattern making, it is possible to use ground-glass, a conventional light diffusion plate containing the light diffusing agent in a transparent substrate and a so-called volume hologram light diffusion plate in which the speckle is recorded as a refraction index distribution of the photosensitive material.

The photosensitive layer of the photosensitive material is then developed by the method depending on the material, to obtain a surface asperity shape. The photosensitive layer of the photosensitive material 9 may be composed of bichromic acid gelatin, an acrylic monomer-combined compound or a photoresist. In the case of the using photoresist, an alkaline aqueous solution may be used as a developer. The stamper for the injection molding may be obtained by making an electrotyped mold on which the asperity face is transcribed from a asperity face of the photosensitive layer in the photosensitive material 9. One example of the method for making a casting mold on which the asperity capable of diffusing the light has been formed is shown in a reference “Zoku Wakariyasui Hikarijiki Disc (Understandable Magnetic Optical Disc) (The Optronics Co., Ltd., published in 1991). That is, a master electrotyped mold may be made by a step of making a asperity pattern of an objective diffusion body on a glass substrate, forming a silver or nickel film on a pattern-formed face by a vacuum deposit method or a spattering method (conductive treatment), and laminating nickel by electrotyping, which is then peeled off the glass plate. This master electrotyped mold may be used as the stamper to form the optical element having plurality of fine asperity.

In the system in FIG. 5, the speckle produced by the laser light which has passed through the light diffusion plate 8 for the pattern making is recorded on the photosensitive material 9 to obtain a hologram surface diffusion pattern. A size, a shape and a direction of the speckle is regulated to control an expanding angle of scattering light regenerated from the resulting optical element with the hologram surface diffusion pattern. Generally, the expanding angle of the scattering light, i.e., an angle distribution of the scattering light depends on an average size and the shape of the speckles. If the speckle is small, the angle distribution is wide. If the speckle is an oval having the longer axis in a horizontal direction, the shape of the angle distribution becomes the oval having the longer axis in a vertical direction. Therefore, it is preferable to control the size and the shape of the speckle recorded in the photosensitive material 9 so as to obtain the correct output or the expanding angle.

The size of the speckle is in inverse proportional to the size of the opening on the shielding face 10. If the size of a pore becomes large, the size of the speckle is reduced, and the expanding angle of the scattering light from the recorded photosensitive material 9 is increased. On the contrary, if the size of the opening on the shielding face 10 is reduced, the size of the speckle recorded in the photosensitive material 9 is increased, and the expanding angle of the scattering light from a recorded photosensitive medium is reduced.

A distance h between the light diffusion plate 8 for the pattern making and the photosensitive material 9 affects the size of the speckle. If the distance h is reduced, the size of the speckle recorded in the photosensitive material 9 is also reduced. On the contrary, if the distance h is increased, the size of the recorded speckle is increased. Therefore, the distance h and the size of the pore in the shielding face 10 are all regulated based on experiences in order to obtain the speckle having the desirable size in the photosensitive material 9.

In the optical element of the present invention, it is preferable that the hologram surface diffusion pattern is composed of the fine asperity shape, the arithmetic average roughness Ra of the asperity shape is 0.5 to 10 μm, and the ratio of the arithmetic average roughness Ra to the mean spacing Sm, i.e., Ra/Sm of the asperity is 0.01 to 0.9.

By falling the arithmetic average roughness Ra of the asperity in the above range, it is possible to reduce luminance unevenness and make occurrence of appearance fault difficult.

The arithmetic average roughness Ra of the asperity is more preferably 1 to 5 μm.

By falling the ratio of the arithmetic average roughness Ra to the mean spacing Sm, i.e., Ra/Sm of the asperity in the above range, it is possible to reduce luminance unevenness and make occurrence of appearance fault difficult.

The ratio of the arithmetic average roughness Ra to the mean spacing Sm, i.e., Ra/Sm of the asperity is more preferably 0.05 to 0.8.

The arithmetic average roughness Ra of the asperity and the mean spacing Sm may be calculated according to JIS B 0601 6. The mean spacing may be obtained by picking a standard length of a asperity roughness curve in its average line direction, calculating a sum of lengths of the average lines corresponding to one mountain and one valley adjacent one another and calculating a mean value thereof. In the present invention, measurement is performed with an ultradeep shape measuring microscope (Keyence, VK-9500), and an evaluation length of 100 μm. The both values of the arithmetic average roughness Ra and the mean spacing Sm are the values measured in the direction along which the arithmetic average roughness Ra is maximized.

The optical element of the present invention may have the hologram surface diffusion pattern only on one surface or on both surfaces.

The display device of the present invention comprises the above optical element of the present invention. The display device of the present invention may be preferably a planar display device.

One example of the display device of the present invention is shown in FIG. 4, although the present invention is not limited to this embodiment. In FIG. 4, the display device has a plurality of cold cathode tubes 3, a reflection plate 4, an optical element 1 on which a hologram surface diffusion pattern is formed, an optical sheet 6 and a liquid crystal panel 7. Light emits from the light source, i.e., the cold cathode tube 3. A part of the emitted light directly enters in the optical element 1. The remaining light enters in the optical element 1 after being reflected by the reflection plate 4. The optical element 1 has the hologram surface diffusion pattern 5, and thus, the entered light uniformly scatters with a high transmittance, and exits toward the optical sheet 6. The optical sheet 6 is composed of a diffusion sheet, a prism sheet and a reflective light polarizer utilizing birefringent proposed in JP Patent No. 3448626 B, which are stacked in the order from the proximity of the optical element. The optical sheet 6 has the functions for regulating the direction of light emission and enhancing the luminance. When the light which has passed through this optical sheet 6 enters into the liquid crystal panel, the pattern formed in the liquid crystal panel may be visually confirmed in a clear manner.

Furthermore, the preferable embodiments when the optical element of the present invention is the light diffusion plate or the light diffusion sheet, and the preferable embodiments of the display device of the present invention may include the followings.

(1) The hologram surface diffusion pattern wherein a maximum value of a half value width (degree) of a light intensity diffused by the hologram surface diffusion pattern is 100 degree or less is suitably used.

This increases an emitting light intensity in a front face direction, and may enhance the luminance of the display device. Explaining the half value width (degree) of the light intensity, generally, the light emitted from one point on the light diffusion plate or the light diffusion sheet having the hologram surface diffusion pattern is different in its light intensity depending on the emitting direction. An angle formed by two light emitting directions which show the half light intensity of the maximum light intensity, which interleaves the light emitting direction of the maximum light intensity on a plane including the light emitting direction of the maximum light intensity is referred to as the half value width (degree) of the light intensity. There are lots of such planes including the light emitting direction of the maximum light intensity in directions which rotate centering around the maximum light intensity direction. A maximum among the half value widths (degrees) of the light intensity on plurality of those planes is referred to as the maximum value of the half value width (degree) of the light intensity.

The maximum value of the half value width (degree) of the light intensity is more preferably 20 to 100 degree and still more preferably 30 to 80 degree. When the maximum value of the half value width of the light intensity is too large, a peripheral portion becomes too bright when the light diffusion plate or the light diffusion sheet is used in the display device. When the maximum value of the half value width of the light intensity is too small, the range brightly displayed tends to become too narrow. It is also preferable that the light emitting direction of the maximum light intensity is a normal line direction of the face on which the hologram surface diffusion pattern has been formed.

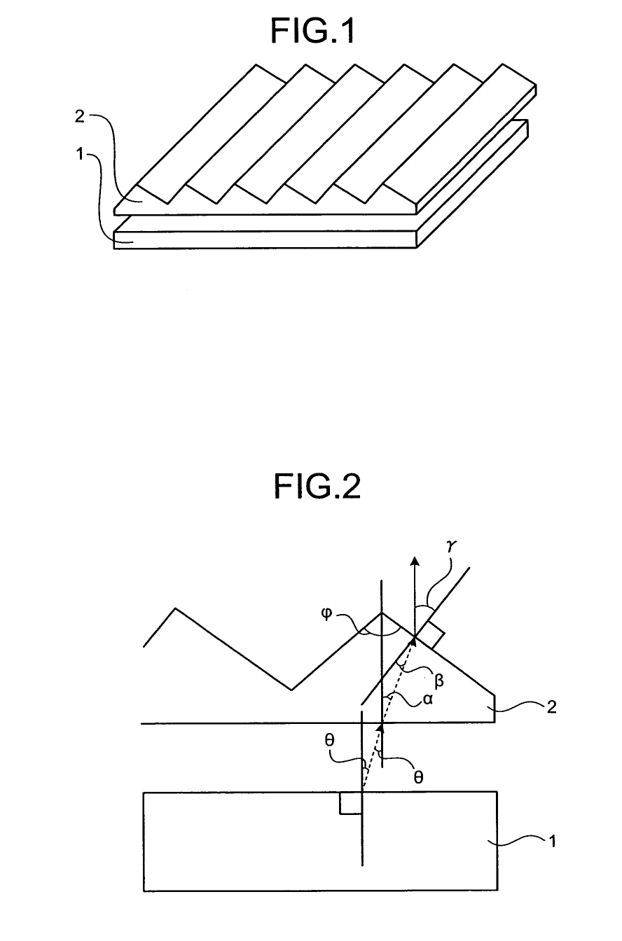

(2) When an upward prism sheet 2 is used in combination on the light diffusion plate or the light diffusion sheet as shown in FIG. 1, it is preferable to use the hologram surface diffusion pattern so that the maximum light intensity direction of the light emitted from the hologram surface diffusion pattern is approximately equal to at least one direction of two directions of the angles θ represented by the following formula against the normal line direction of the face on which the hologram surface diffusion pattern is formed, on the plane perpendicular to a ridgeline of a prism as shown in FIG. 2.

θ is the angle calculated by the following formulae, and depends on only the material of the prism sheet and the shape of the prism.

Sin α/Sin θ=1/n1 Formula (1)

Sin γ/Sin β=n2 Formula (2)

α=90−(Φ/2+β) Formula (3)

γ=90 −Φ/2 Formula (4)

In FIG. 2, Φ is a prism apex angle of the prism sheet 2. This is a constant number determined by the prism shape of the prism sheet. And, n1 is a refraction index of a prism opposite face of the prism sheet, and n2 is a refraction index of a prism face of the prism sheet. These are constant numbers determined by the material of the prism sheet. And, α, β and γ are the angles shown in FIG. 2, and may be calculated from Φ and n as described below.

By the formula (4), γ is calculated from the prism apex angle Φ. By the formula (2), β is calculated from the refraction index n of the prism and y. From the formula (3), α is calculated, and finally θ is calculated from the formula (1).

In the most preferable embodiment of the present invention, an intensity distribution of the light emitted by the hologram surface diffusion pattern 5 is the maximized in at least one direction in two direction of θ in FIG. 2. Being “approximately equal to the angle θ” refers to that the direction of the maximum value of the light emitted by the hologram surface diffusion pattern 5 is within 30 degree from θ in FIG. 2, and this angle is preferably within 20 degree and more preferably within 10 degree.

In order to incline the direction of the maximum value of the light emitted from the hologram surface diffusion pattern by θ from the normal line direction of the emitting face, the photosensitive material 9 shown in FIG. 5 may be exposed by disposing it in an inclined direction from the perpendicular direction against the direction of the laser light toward the light source. Alternatively, both side or an opposite side of the plate on which the hologram surface diffusion pattern is provided may be provided with a diffraction grating which diffracts the light to the aforementioned 0 direction.

The light may be efficiently used and the luminance of the display device may be enhanced by inclining the direction of the maximum value of the light emitted from the hologram surface diffusion pattern by θ from the normal line of the emitting face and inclining the light entering into the prism sheet by θ from the normal line of the prism sheet.

(3) It is preferable to use the hologram surface diffusion pattern wherein the maximum intensity direction of the emitted light is equal to an approximate normal line direction of the emitting face when an incident angle of the light which enters in the light diffusion plate or the light diffusion sheet is within 45° against the normal line of an incident face. In this embodiment, luminance of the display device may be enhanced when a plurality of light sources are used in combination, since the light from light sources at both sides adjacent to a particular light source just below a particular position in the light diffusion plate or the light diffusion sheet may be emitted toward the front face direction. An “approximate normal line direction” of the emitting face refers to the direction within 30 degree against the normal line of the emitting face, and this angle is preferably within 20 degree and more preferably within 10 degree.

The hologram surface diffusion pattern in which the maximum intensity direction of the emitted light is equal to the approximate normal line direction of the emitting face when the incident angle of the light which enters in the light diffusion plate or the light diffusion sheet is within 45° against the normal line of the incident face may be obtained by optionally setting the distance h between the light diffusion plate 8 for pattern making and the photosensitive material 9 and the sizes W and L of the opening of the shielding face 10 when the hologram surface diffusion pattern is made as shown in FIG. 5.

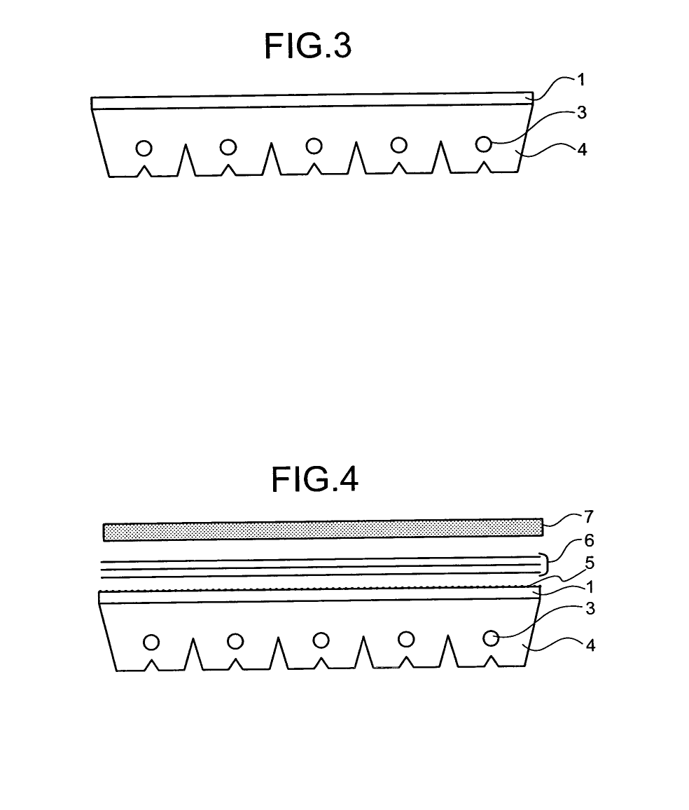

(4) The preferable display device of the preferable embodiment comprises a panel disposed on the light diffusion plate or the light diffusion sheet, a plurality of cold cathode tubes disposed below the light diffusion plate or the light diffusion sheet, and a reflection plate disposed below the cold cathode tubes, wherein the reflection plate has a protrusion in ridge shape. It is desirable that the ridge protrusion is located at least one of an intermediate portion between adjacent cold cathode tubes and a position just below the cold cathode tube. For example, in FIG. 3, the light which has escaped oblique downwards may be reflected upwards by the larger ridge protrusions in the intermediate portion between the cold cathode tubes, to thereby prevent the intermediate portion between the cold cathode tubes from becoming dark. The light emitted just below the cold cathode tubes may be reflected toward the adjacent cold cathode tubes by the smaller ridge protrusions just below the cold cathode tubes, to thereby avoid interference of the cold cathode tubes themselves with the light discharge.

(5) It is preferable to use the hologram surface diffusion pattern in which the half value width (degree) of the light intensity is large around just above the cold cathode tube and the half value width (degree) of the light intensity is small in the intermediate portion between the cold cathode tubes, in an embodiment having a panel disposed on the light diffusion plate or the light diffusion sheet, a plurality of cold cathode tubes disposed below the light diffusion plate or the light diffusion sheet, and a reflection plate disposed below the cold cathode tubes. The luminance of the display device may be made uniform by largely diffusing the light on a lamp. Such a hologram surface diffusion pattern may be produced by, upon light exposure, partially forming the half value width (degree) of a certain light intensity by shielding a part of the photosensitive material, and subsequently forming a different half value width (degree) while shielding the exposed portion.

(6) It is preferable to etch the opposite surface of the hologram surface diffusion pattern on the light diffusion plate or the light diffusion sheet. It is also preferable to contain a light diffusing agent in addition to the resin having the alicyclic structure in the light diffusion plate or the light diffusion sheet. Since the hologram surface diffusion pattern is the fine shape, the performance is reduced when injured. However, such a reduction of the performance may be offset in this embodiment. Examples of the preferable light diffusing agent may include at least one selected from the group consisting of fine particles composed of polystyrene polymers, polysiloxane polymers or crosslinked compounds thereof, calcium carbonate, silica and talc.

(7) It is preferable to transcribe the shape well on the overall face using pin gates when the light diffusion plate or the light diffusion sheet is injection-molded. Particularly, the effect is remarkable if the method proposed in JP 2004-117544-A is used.

(8) A thickness of the light diffusion plate or the light diffusion sheet is preferably 0.01 mm or more, more preferably 0.1 mm or more and particularly preferably 1 mm or more. By increasing the thickness, it is possible to impart the strength and suppress the deformation in use. An upper limit of the thickness may be 10 mm.

(9) It is preferable that the light diffusion plate or the light diffusion sheet is an approximate rectangle having the diagonal of 400 mm or more. By the use of the resin having the alicyclic structure, it is possible to obtain the uniform performance even in the large size.

(10) It is preferable to use the light diffusion plate or the light diffusion sheet having total light transmittance of 65% or more in the region of 380 nm to 780 nm in terms of increasing the luminance of the display device.

(11) The planar display device in which the light source is LED or the cold cathode tube is preferable. Having LED or the cold cathode tube as the light source, a point light source or a line light source may be exchanged into the plane, and thus, the luminance of the planar display device may be increased and made uniform.

(12) The display device in which the hologram surface diffusion pattern formed on the light diffusion plate or the light diffusion sheet is disposed at the panel side is preferable. By disposing the light diffusion plate or the light diffusion sheet in this way, the incident light and the emitted light are well-balanced and the luminance of the display device may be increased and made uniform.

(13) It is preferable that a prism, a microlens, low reflection treatment and a diffraction grating are formed at the face opposed to the side on which the hologram surface diffusion pattern has been formed on the light diffusion plate or the light diffusion sheet. Such a light diffusion plate or the light diffusion sheet is preferable because the performance of the light diffusion plate or the light diffusion sheet may be increased. In the same way as in the aforementioned embodiment (5), properties of these constituents may vary depending on whether the position on the surface is around just above the light source or just above the intermediate portion between the light sources.

### EXAMPLES

The present invention will be specifically described by showing Examples and Comparative examples below, but the invention is not limited to the following Examples. Unless otherwise indicated, “parts” represents parts by weight.

### Preparative Example 1

### Production of Norbornene Polymer

To a pressure resistant vessel made of stainless thoroughly dried at room temperature and substituted with nitrogen, 500 parts of dehydrated cyclohexane, 0.82 parts of 1-hexene, 0.15 parts of dibutyl ether and 0.30 parts of triisobutyl aluminium were added and mixed. Subsequently with keeping the temperature at 45° C., 170 parts of tricyclo[4.3.0.1^{2,5}]deca-3,7-diene (also known as: dicyclopentadiene, abbreviated hereinbelow as “DCP”), 30 parts of 8-ethylidene-tertacyclo[4.4.0.1^{2,5}.1^{7,10}]-dodeca-3-ene (also known as: ethylidenetetracyclododecene, abbreviated hereinbelow as “ETD”) and 30 parts of tungsten hexachloride (0.7% toluene solution) were sequentially added thereto over 2 hours to perform polymerization. To the polymerization solution, 1.06 parts of butyl glycidyl ether and 0.52 parts of isopropyl alcohol were added thereto, to stop a polymerization reaction to yield the solution including a DCP/ETD ring-opening copolymer.

Then, 270 parts of cyclohexane was added to 100 parts of the resulting solution including the ring-opening copolymer. Further 5 parts of nickel-alumina catalyst (supplied from JGC corporation) was added thereto as a hydrogenation catalyst. The pressure was applied to 5 MPa with hydrogen and temperature was raised up to 200° C. with stirring, and the reaction was performed for 4 hours to yield the solution containing 20% hydrogenated DCP/ETD ring-opening copolymer. After removing the hydrogenation catalyst by filtration, 0.1 part of pentaerythrityl-tetraxis[3-(3,5-di-t-butyl-4-hydroxyphenyl)propionate] as a phenol antioxidant per 100 parts of the hydrogenated copolymer was added to the resulting solution and dissolved. Then, using a cylindrical concentrating dryer (supplied from Hitachi Ltd.), as the solvents including cyclohexane and other volatile components were removed from the solution at a temperature of 270° C. and pressure of 1 kPa or less, the hydrogenated product in a melted state was extruded into a strand shape by an extruder, which was then cooled and pelletized to collect pellets. A weight average molecular weight (Mw), a hydrogenated rate and Tg of this ring opening hydrogenated copolymer was 35,000, 99.9% and 143° C., respectively.

### Preparative Example 2

### Production of Hologram Surface Diffusion Pattern

A photosensitive material 9 was made by coating a glass substrate with a photoresist (ZPP-1800, supplied from Zeon Corporation). In the optical system of FIG. 5, a ground-glass was provided as a light diffusion plate for pattern making, and a distance h between the light diffusion plate 8 for pattern making and the photosensitive material 9, and a size W and L of an opening of a shielding face were suitably adjusted. Light exposure was performed with argon laser as coherent light 11 at a wavelength of 488 nm at 50 mJ/cm². After the development with a developer specifically prepared therefor, a hologram surface diffusion pattern was obtained.

A thin film of nickel was deposited onto this pattern by spattering. Further electrotyping with a thickness of 500 μm using a nickel sulfamate solution, a stamper with the hologram surface diffusion pattern was obtained. Ra, Sm and Ra/Sm of this stamper were 2.1 μm, 4.8 μm and 0.44, respectively.

### Example 1

The stamper obtained in Preparative Example 2 was attached in a metal mold having a cavity of a length of 320.0 mm, a width of 426.0 mm and a depth of 2.0 mm, which was further attached to an injection-molding machine (mold clamping force: 3,430 kN). The DCP/ETD ring opening hydrogenated copolymer obtained in Preparative Example 1 was then injection-molded under the conditions of a cylinder temperature at 290° C., a mold temperature at 85° C., an injection speed at 100 mm/s and a cooling time for 50 seconds to form a 20 inch light diffusion plate (1) having the hologram surface diffusion pattern on one surface. The resulting light diffusion plate (1) was disposed on a surface table and an uplift height at a side face was measured using a micrometer caliper. Consequently the height was as small as 0.1 mm. Ra and Sm of the face having the hologram surface diffusion pattern on the resulting light diffusion plate (1) were measured, and consequently Ra, Sm and Ra/Sm were 2 μm, 4.8 μm and 0.41, respectively. The maximum value of the half value width of the light intensity of the resulting light diffusion plate (1) was 60°.

A direct type backlight was obtained by decomposing a commercially available liquid crystal television, and only the light diffusion plate was removed therefrom. The light diffusion plate (1) obtained above was disposed therein so that the hologram surface diffusion pattern faced the light source side to make another direct backlight. This backlight was re-installed in the liquid crystal television to make a liquid crystal television (1). The optical sheets such as prism sheet, and the liquid crystal panel in the commercially available liquid crystal television were disposed on the light diffusion plate (1) as they were. Displaying only white signals on the liquid crystal panel, the luminance on the liquid crystal panel was measured for total 81 points of 9 rows in a horizontal direction and 9 rows in a vertical direction with the same interval using a color luminance meter to calculate their average luminance and luminance unevenness. The luminance unevenness was calculated by the following formula, and it is meant that the larger this numerical value is, the less the luminance unevenness is.

Luminance unevenness=(Minimum luminance/Maximum luminance)×100(%)

As a result of measuring the luminance, the average luminance and the luminance unevenness were 469 cd/m² and 78%, respectively.

When observed without the liquid crystal panel and the optical sheet, the images of the cold cathode tubes were scarcely observed on the light diffusion plate. When the luminance was measured after leaving stand the above liquid crystal television (1) in a constant temperature and constant humidity bath at 60° C. and 90% RH (relative humidity) for 200 hours, the average luminance and the luminance unevenness were 468 cd/m² and 78%, respectively, i.e., they were scarcely changed.

When the surface of the molded light diffusion plate and the surface of the stamper were observed by SEM (scanning electron microscope), no large difference was observed between them and it was confirmed that the pattern had been accurately transcribed.

### Example 2

A liquid crystal television (2) was prepared in the same way as in Example 1 except that the light diffusion plate (1) in Example 1 was disposed so that the hologram surface diffusion pattern was on the surface facing the liquid crystal panel (opposed to the light source), and the luminance was measured. Consequently the average luminance and the luminance unevenness were 470 cd/m² and 80%, respectively. When observed without the liquid crystal panel and the optical sheet, the images of the cold cathode tubes were scarcely observed on the light diffusion plate.

Further, the luminance was measured after leaving stand the above liquid crystal television (2) in the constant temperature and constant humidity bath at 60° C. and 90% RH (relative humidity) for 200 hours in the same way as in Example 1. Consequently, the average luminance and the luminance unevenness were 469 cd/m² and 80%, respectively.

### Example 3

99.7 parts of the DCP/ETD ring-opening hydrogenated copolymer that has been produced in Preparative Example 1 and 0.3 parts of fine particles composed of crosslinked polysiloxane polymer (Tospearl 120, GE Toshiba Silicone) were mixed. The mixture was extruded using a biaxial extruder to be in a strand shape and cut using a pelletizer, to prepare pellets for the light diffusion plate. A light diffusion plate (2) was obtained by performing the injection-molding in the same way as in Example 1 except for using these pellets. Ra and Sm of the face having the hologram surface diffusion pattern on the resulting light diffusion plate (2) were measured, and consequently Ra, Sm and Ra/Sm were 2 μm, 4.8 μm and 0.41, respectively. The maximum value of the half value width of the light intensity of the resulting light diffusion plate (2) was 70°.

A liquid crystal television (3) was made in the same way as in Example 1 except that the light diffusion plate (2) was disposed so that the hologram surface diffusion pattern was on the surface facing the liquid crystal panel (opposed to the light source). The same evaluation as in Example 1 was performed for the liquid crystal television (3). Consequently the average luminance and the luminance unevenness were 468 cd/m² and 83%, respectively. When observed without the liquid crystal panel and the optical sheet, the images of the cold cathode tubes were scarcely observed on the light diffusion plate.

Further, the luminance was measured after leaving stand the above liquid crystal television (3) in the constant temperature and constant humidity bath at 60° C. and 90% RH (relative humidity) for 200 hours in the same way as in Example 1. Consequently, the average luminance and the luminance unevenness were 470 cd/m² and 78%, respectively

### Example 4

Measuring the prism sheet used in the commercially available liquid crystal television used in Example 1, the refraction index n and the prism apex angle were 1.49 and 90°, respectively. Based on these numerical values, the optimal output angle θ calculated from the above formulae (1) to (4) was 25°. Thus, a diffraction grating having a primary diffraction angle at a 25° direction and a primary diffraction efficiency of 100% at a wavelength of 550 nm was designed according to the reference (“Kaisetsu Kogaku Soshi Nyumon [Introduction for Diffraction Optical Devices]” published by Optronics Co., Ltd., pages 64 to 65), and the diffraction grating pattern was formed on the face opposed to the side of the hologram surface diffusion pattern on the light diffusion plate (1) in Example 1 by cutting using an ultraprecise molding planar grinding machine (supplied from Nagase Integrex Co., Ltd.) to obtain a light diffusion plate (3). A liquid crystal television (4) was obtained by disposing the light diffusion plate (3) so that the hologram surface diffusion pattern was on the surface facing the liquid crystal panel (opposed to the light source). The same evaluation as in Example 1 was performed for the liquid crystal television (4). Consequently the average luminance and the luminance unevenness were 474 cd/m² and 82%, respectively. When observed without the liquid crystal panel and the optical sheet, the images of the cold cathode tubes were scarcely observed.

Further, the luminance was likewise measured after leaving stand the above liquid crystal television (4) in the constant temperature and constant humidity bath at 60° C. and 90% RH (relative humidity) for 200 hours. Consequently, the average luminance and the luminance unevenness were 473 cd/m² and 82%, respectively.

### Example 5

A light diffusion plate (4) was obtained by forming a diffraction grating with a width of 10 mm having the same shape as in Example 4 just above the cold cathode tubes of the direct type backlight, on the face opposed to the surface on which the hologram surface diffusion pattern had been formed on the light diffusion plate (1) obtained in Example 1. A liquid crystal television (5) was made by disposing the light diffusion plate (4) so that the hologram surface diffusion pattern was on the surface facing the liquid crystal panel (opposed to the light source). The same evaluation as in Example 1 was performed for the liquid crystal television (5). Consequently the average luminance and the luminance unevenness were 476 cd/m² and 83%, respectively. When observed without the liquid crystal panel and the optical sheet, the images of the cold cathode tubes were scarcely observed on the light diffusion plate (4).

Further, the luminance was likewise measured after leaving stand the above liquid crystal television (5) in the constant temperature and constant humidity bath at 60° C. and 90% RH (relative humidity) for 200 hours. Consequently, the average luminance and the luminance unevenness were 475 cd/m² and 83%, respectively.

### Example 6

Milk white triangle prisms made of plastic were prepared. The prism had a sectional shape of a right angled isosceles triangle having a base of 18 mm and a height of 9 mm. A white reflection sheet (White Refstar WS-180, supplied from Mitsui Chemicals) was attached to this triangle prism. These prisms were attached to one face of the reflection plate disposed in the commercially available liquid crystal television used in Example 1, to obtain a reflection plate provided with protrusions. The triangle prisms were attached so that the apex angle thereof was 90° when attached to the reflection plate. The prisms were disposed in the intermediate position between the adjacent cold cathode tubes.

A liquid crystal television (6) was made by disposing the light diffusion plate (1) in the same way as in Example 2 except for using the reflection plate provided with the protrusions. The same evaluation as in Example 1 was performed for the liquid crystal television (6). Consequently the average luminance and the luminance unevenness were 472 cd/m² and 82%, respectively. When observed without the liquid crystal panel and the optical sheet, the images of the cold cathode tubes were scarcely observed on the light diffusion plate (1).

Further, the luminance was likewise measured after leaving stand the above liquid crystal television (6) in the constant temperature and constant humidity bath at 60° C. and 90% RH (relative humidity) for 200 hours. Consequently, the average luminance and the luminance unevenness were 471 cd/m² and 82%, respectively.

### Comparative Example 1

A liquid crystal television was made in the same way as in Example 1 except for using a commercially available light diffusion plate made of acrylic resin (RM-401 supplied from Sumitomo Chemical Industries, which may be referred to hereinbelow as a “light diffusion plate (5)”) as the light diffusion plate, and the same evaluation as in Example 1 was performed. Consequently the average luminance and the luminance unevenness were 450 cd/m² and 80%, respectively. When observed without the liquid crystal panel and the optical sheet, images of the cold cathode tubes were scarcely observed on the light diffusion plate (5).

Further, the luminance was likewise measured after leaving stand the liquid crystal television in a constant temperature and constant humidity bath at 60° C. and 90% RH (relative humidity) for 200 hours. Consequently, the average luminance and the luminance unevenness were 445 cd/m² and 73%, respectively.

### Comparative Example 2

A light diffusion plate (6) having the hologram surface diffusion pattern formed on one surface thereof was obtained by performing the injection-molding in the same way as in Example 1 except for using a commercially available acrylic resin (Delpet 80NH supplied from Asahi Kasei Corporation) in place of the resin obtained in Preparative Example 1. The resulting light diffusion plate (6) was disposed on the surface table and the uplift height at the side face was measured using the micrometer caliper. Consequently the height was as large as 1.0 mm. Ra and Sm of the face having the hologram surface diffusion pattern in the resulting light diffusion plate (6) were measured, and consequently Ra, Sm and Ra/Sm were 1.1 μm, 4.9 μm and 0.22, respectively.

When the surface of the light diffusion plate (6) and the surface of the stamper were observed by SEM, it was confirmed that the pattern had not been transcribed well on the surface of the light diffusion plate.

A liquid crystal television was made by disposing the light diffusion plate (6) in the same way as in Example 2 except for using this light diffusion plate (6). The same evaluation as in Example 1 was performed for this liquid crystal television. Consequently the average luminance and the luminance unevenness were 410 cd/m² and 60%, respectively. When observed without the liquid crystal panel and the optical sheet, the images of the cold cathode tubes were observed on the light diffusion plate (6). Further, the luminance was likewise measured after leaving stand the liquid crystal television in a constant temperature and constant humidity bath at 60° C. and 90% RH (relative humidity) for 200 hours. Consequently, the average luminance and the luminance unevenness were 403 cd/m² and 58%, respectively.

From these results, it has been confirmed that the light diffusion plates in Examples 1 to 6 composed of the resin containing the alicyclic structure have both the good light diffusion performance and the good light transmittance, and are less subject to the environmental influence. On the contrary, as shown in Comparative Example 1, with the light diffusion plate composed of the acrylic resin and having no hologram surface diffusion pattern, the average luminance is low and the luminance unevenness is large. As is shown in Comparative Example 2, on the light diffusion plate composed of the acrylic resin and having the hologram surface diffusion pattern, the hologram surface diffusion pattern was not accurately transcribed, and thus the average luminance was reduced and the luminance unevenness was increased. When left stand in the constant temperature and constant humidity bath at 60° C. and 90% RH (relative humidity) for 200 hours, the performance of the light diffusion plates in Examples 1 to 6 was scarcely changed, whereas the luminance unevenness of the light diffusion plates in Comparative Examples 1 and 2 was remarkably deteriorated.

According to the optical element and the display device by the use thereof of the present invention, the fine hologram surface diffusion pattern is precisely formed. Therefore, it is possible to obtain the optical element and the display device by the use thereof in which both the good light diffusion performance and the good light transmittance are achieved and which are less subject to the environmental influence.

1. An optical element comprising a molded body containing a resin having an alicyclic structure, said molded body having a hologram surface diffusion pattern formed on at least one surface thereof.

2. The optical element according to claim 1 wherein the hologram surface diffusion pattern is composed of a fine asperity, an arithmetic average roughness Ra of the asperity is 0.5 to 10 μm, and a ratio of the arithmetic average roughness Ra to a mean spacing Sm (Ra/Sm) of the asperity is 0.01 to 0.9.

3. The optical element according to claim 1 wherein the optical element has a single layer structure.

4. The optical element according to claim 1 wherein the optical element is a light diffusion plate or a light diffusion sheet.

5. The optical element according to claim 1 wherein said surface has a rectangular planar shape and a length of its diagonal is 200 mm or more.

6. The optical element according to claim 1 wherein said element is obtained by injection molding.

7. A display device comprising the optical element according to claim 1.

8. A method for producing the optical element according to claim 1 comprising:
a step of preparing a stamper having a fine asperity formed on its surface, wherein an arithmetic average roughness Ra of the asperity is 0.5 to 10 μm, and a ratio of the arithmetic average roughness Ra to a mean spacing Sm(Ra/Sm) of the asperity is 0.01 to 0.9,
a step of providing with a mould where said stamper has been incorporated, and
a step of injection-molding a resin having an alicyclic structure using said mould, to obtain a molded body wherein said fine asperity on the surface of said stamper is transcribed on a surface of said molded body.
